(19) United States
(12) Patent Application Publication
(10) Pub. No.: US 2005/0239286 A1
(43) Pub. Date: Oct. 27, 2005

(54) TWO-STEP STRIPPING METHOD FOR REMOVING VIA PHOTORESIST DURING THE FABRICATION OF PARTIAL-VIA DUAL DAMASCENE FEATURES

(76) Inventors: Chih-Ning Wu, Hsin-Chu City (TW); Wen-Liang Lien, Taipei City (TW); Charlie CJ Lee, Hsin-Chu Hsien (TW); Meiling Li, Chia-I City (TW)

Correspondence Address: NORTH AMERICA INTELLECTUAL PROPERTY CORPORATION, P.O. BOX 506, MERRIFIELD, VA, 22116, US

(21) Appl. No.: 10/904,151

(22) Filed: Oct. 27, 2004

(30) Foreign Application Priority Data
Apr. 23, 2004 (TW) 093111450

(51) Int. Cl. H01L 21/4763

(52) U.S. Cl. 438/637; 438/725; 438/952

(57) ABSTRACT

A two-step stripping method for removing via photoresist during the fabrication of trench-first partial-via dual damascene features is disclosed. In the first cleaning step, inert gas (He, Ar, N₂)/fluorocarbon plasma is used to contact the remaining “Via Photo” for a short time period not exceeding 20 seconds. Thereafter, in the second cleaning step, a reducing plasma is used to completely strip the remaining “Via Photo”, thereby preventing the low-k or ultra low-k carbon-containing dielectric layer from potential carbon depletion.

### BACKGROUND OF INVENTION

1. Field of the Invention

The present invention relates to metal interconnect dual damascene processes. More particularly, the present invention relates to a two-step stripping method for preventing carbon depletion of low-k or ultra low-k dielectric during the fabrication of trench-first partial-via dual damascene structures.

2. Description of the Prior Art

To meet the need of high integration and high processing speed of integrated circuits (ICs) of 0.13 micron or nano-scale generations, a Cu interconnect technology has now become an effective solution. Cu is approximately 40% lower in resistivity than Al and has fewer reliability concerns such as electromigration. Cu interconnect technology, by and large, has been implemented employing damascene techniques, wherein an ILD, such as a silicon oxide layer, e.g., derived from tetraethyl orthosilicate (TEOS) or silane, or a low-k material, is formed over an underlying metal level containing metal features, e.g., Cu or Cu alloy features with a silicon nitride capping layer. A damascene opening, e.g., via hole, trench, or dual damascene opening, is then formed in the ILD. A barrier layer and optional seed layer are then deposited, followed by Cu deposition, as by electrodeposition or electroless deposition. As the technology node advances from 180 to 45 nm, the ILD evolves from F—SiO₂, through organosilicate glass (OSG) and now to ultra low-k (ULK, K<2.5) materials.

The biggest concern associated with using prior art low-k strip is the alteration of the carbon-containing low-k dielectric materials. FIG. 1 through FIG. 6 illustrate, in cross sectional views, six main stages for fabricating a trench-first partial-via dual damascene feature by using 193 nm photoresist. In stage one, as shown in FIG. 1, a low-k dielectric layer 1, a SiC layer 2, a metal layer 3, a silicon oxide layer 4, and a bottom anti-reflective coating (BARC) layer 5 are sequentially deposited on a surface of a semiconductor substrate (not shown), more specifically, on a surface of a capping silicon nitride layer. A layer of 193 nm photoresist (also referred to as “Trench Photo”) 6 having an open trench pattern 7 thereon is situated on the BARC layer 5. The metal layer 3 is typically composed of TiN or TaN.

Proceeding to stage two, as shown in FIG. 2, the stacked hard mask consisting of the SiC layer 2, the intermediate metal layer 3, and the silicon oxide layer 4 is etched through the trench opening 7 to form a trench opening 8 in the stacked hard mask. The etching stops on the SiC layer 2. The remaining Trench Photo layer 6 and BARC layer 5 are then stripped off.

As shown in FIG. 3, in stage three, a BARC layer 9 is coated on the stacked hard mask and fills the trench opening 8. Another pattern of 193 nm photoresist (also referred to as “Via Photo”) 10 is then formed on the BARC layer 9. The Via Photo layer 10 has a via opening 11 patterned by using conventional 193 nm lithography.

Subsequently proceeding to stage four, as shown in FIG. 4, using the Via Photo layer 10 as an etching hard mask, the BARC layer 9, the SiC layer 2, and the dielectric layer 1 are etched through the via opening 11, thereby forming a partial via feature 12 in an upper portion of the dielectric layer 1.

Then proceeding to stage five, as shown in FIG. 5, the remaining Via Photo layer 10 and the BARC layer 9 are stripped off by using oxidizing oxygen plasma. The oxidizing oxygen plasma is effective to remove the complex residues (not shown) and remaining 193 nm Via Photot layer 10 from the wafer surface. However, as aforementioned, the oxidizing plasma strip also adversely affects the exposed carbon-containing low-k dielectric layer 1. Highly reactive oxygen radicals and ions penetrate hundreds of angstroms into the exposed carbon-containing low-k dielectric layer 1 and deplete carbons therein. The damaged C-depleted layer 13 is indicated in FIG. 5.

Referring to FIG. 6 and briefly back to FIG. 5, in stage 6, the trench pattern 8 in the hard mask and the partial via feature 12 are transferred to the underlying dielectric layer 1 by reactive ion etching (RIE). Since the exposed dielectric surface within the partial via feature 12 is damaged (or C-depleted), the resultant trench has a distorted profile and fluctuating critical dimension (CD) after RIE. The designed trench profile is indicated by dash line.

### SUMMARY OF INVENTION

Accordingly, the main objective of the claimed invention is to provide an improved dual damascene method incorporated with improved photoresist strip to solve the above-mentioned problems.

According to the claimed invention, a two-step stripping method for removing via photoresist during the fabrication of trench-first partial-via dual damascene features is disclosed. A semiconductor substrate provided thereon with a dielectric layer, a hard mask layer over the dielectric layer, and a first bottom anti-reflection coating (BARC) layer over the hard mask layer is prepared. The hard mask layer comprises a metal layer. On the first BARC layer, a pattern of a trench photoresist layer comprising a trench opening exposing a portion of the subjacent first BARC layer is formed. The exposed first BARC layer and the underlying hard mask layer are etched through the trench opening to form a trench recess in the hard mask layer. The trench photoresist layer and the first BARC layer are stripped off. A second BARC layer is deposited over the hard mask layer and filling the trench recess thereof. On the second BARC layer, a pattern of a via photoresist layer comprising a via opening is formed. The via opening is located above the trench recess, thereby exposing a portion of the subjacent second BARC layer. The exposed second BARC layer, the underlying hard mask layer and the dielectric layer are etched through the via opening to form a via recess in an upper portion of the dielectric layer. The remaining via photoresist layer is stripped using a two-step cleaning process comprising a first cleaning step: contacting the via photoresist layer with hydrogen-free fluorocarbon plasma in a short period of time not exceeding 20 seconds, and thereafter, proceeding a second cleaning step: completely removing the via photoresist layer by using reducing plasma.

Other objects, advantages and novel features of the invention will become more clearly and readily apparent from the following detailed description when taken in conjunction with the accompanying drawings.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention. In the drawings:

FIG. 1 through FIG. 6 illustrate, in cross sectional views, six main stages for fabricating a trench-first partial-via dual damascene feature by using 193 nm photoresist; and

FIG. 7(a) and FIG. 7(b) are cross-sectional diagrams illustrating one preferred embodiment according to the present invention.

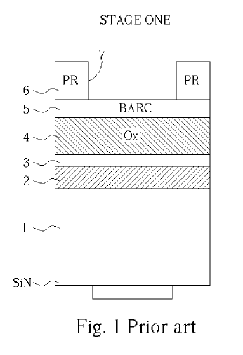

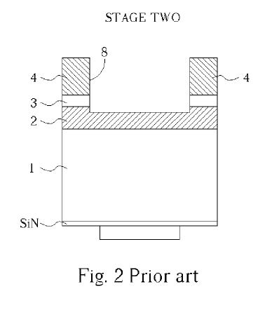

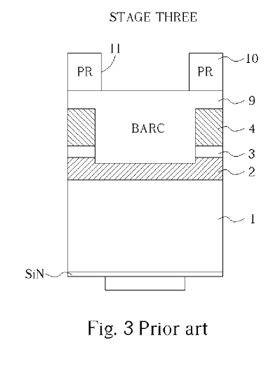

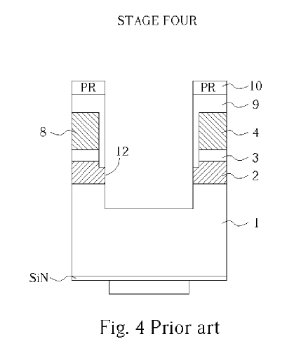

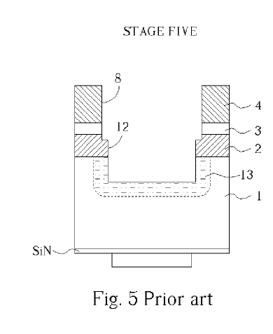

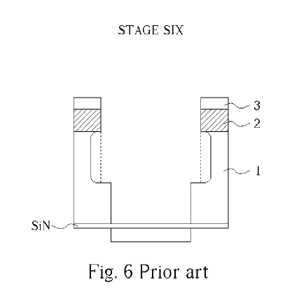

### DETAILED DESCRIPTION

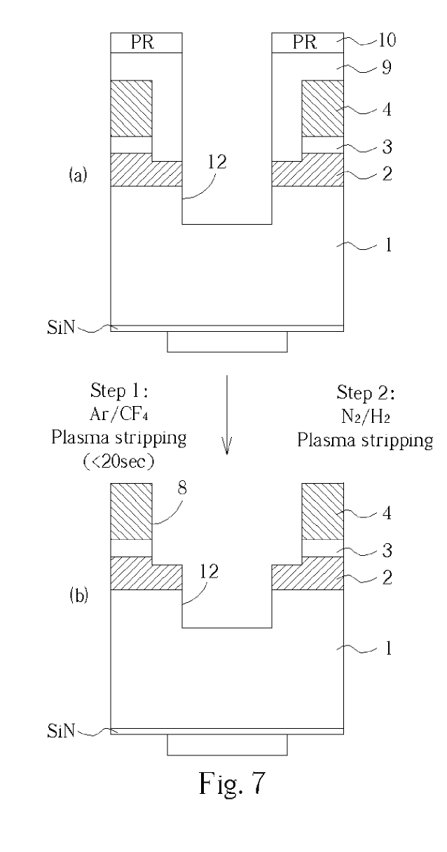

Please refer to FIG. 7(a) and FIG. 7(b). FIG. 7(a) and FIG. 7(b) are cross-sectional diagrams illustrating the low-k dielectric with partial via and hard mask thereon, respectively, according to one preferred embodiment of the present invention. The present invention of fabricating a partial-via dual damascene feature in a dielectric layer basically includes six main stages as previously described in the prior art section of this application. Since the dual damascene fabrication steps from the first stage to the fourth stage are substantially the same as the prior art, they are omitted for the sake of simplicity. The discussion of the preferred embodiment will now begin on stage four.

In stage four, as shown in FIG. 7(a), likewise, using the 193 nm photoresist layer (Via Photo) 10 as an etching hard mask, the BARC layer 9, the SiC layer 2, and the dielectric layer 1 are dry etched through the via opening 11, thereby forming a partial via feature 12 in an upper portion of the dielectric layer 1. According to the preferred embodiment, preferably, the metal layer 3 is made of titanium nitride (TiN) or tantalum nitride (TaN), but not limited thereto. The dielectric layer 1 may be CVD-type carbon-doped silicon oxide, black diamond by Applied Materials Co., or any carbon-containing ULK materials. Thereafter, instead of the prior art pure oxygen plasma ashing/stripping for removing the Via Photo 10 and the BARC layer 9, the present invention uses a two-step strip process flow. In the first cleaning step, the Via Photo 10 is subjected to plasma created by a mixture etching gas containing inert gas (such as helium, argon, or nitrogen) and fluorocarbon substance, wherein the fluorocarbon substance contains no hydrogen such as carbon tetra-fluoride (CF₄) or C₂F₆. It is noted that the first cleaning step must be terminated in a short period of time not exceeding 20 seconds before depleting any carbon in the exposed dielectric layer 1. According to the preferred embodiment, by way of example, argon with a flow rate of 200 sccm (standard cubic centimeters per minute) and carbon tetra-fluoride (CF₄) with a flow rate of 5˜10 sccm are preferred. In this case, the contact time will be less than 20 seconds, preferably 10 seconds.

The CF₄ plasma can effectively remove metal derivatives deposited on the surface of the remaining Via Photo 10 without significant carbon depletion. It is to be understood that if the contact time exceeds 20 seconds, the CF₄ plasma will start to deplete carbon within the exposed dielectric layer 1. It is further noted that fluorine-substituted hydrocarbons e.g., fluoroform (CHF₃) are not suited for replacing the fluorocarbon because polymer crusts might be formed. Subsequently, the remaining Via Photo 10 is completely removed by using reducing plasma such as N₂/H₂, He/H₂, or NH₃ Plasma. In another case, a final wet cleaning step may also be needed to remove any remaining residues. After the two-step cleaning process, the trench pattern 8 in the hard mask and the partial via feature 12 are transferred to the underlying dielectric layer 1 by reactive ion etching (RIE).

Those skilled in the art will readily observe that numerous modification and alterations of the device may be made while retaining the teachings of the invention. Accordingly, the above disclosure should be construed as limited only by the metes and bounds of the appended claims.

1. A two-step stripping method for removing via photoresist during the fabrication of trench-first partial-via dual damascene features, comprising:
preparing a semiconductor substrate provided thereon with a dielectric layer, a hard mask layer over the dielectric layer, and a first bottom anti-reflection coating (BARC) layer over the hard mask layer, wherein the hard mask layer comprises a metal layer;
forming, on the first BARC layer, a pattern of a trench photoresist layer comprising a trench opening exposing a portion of the subjacent first BARC layer;
etching the exposed first BARC layer and the underlying hard mask layer through the trench opening to form a trench recess in the hard mask layer;
stripping the trench photoresist layer and the first BARC layer;
depositing a second BARC layer over the hard mask layer and filling the trench recess thereof;
forming, on the second BARC layer, a pattern of a via photoresist layer comprising a via opening, which is located above the trench recess, thereby exposing a portion of the subjacent second BARC layer;
etching the exposed second BARC layer, the underlying hard mask layer and the dielectric layer through the via opening to form a via recess in an upper portion of the dielectric layer; and
stripping the via photoresist layer using a two-step cleaning process comprising a first cleaning step: contacting the via photoresist layer with hydrogen-free fluorocarbon plasma in a short period of time not exceeding 20 seconds, and thereafter, proceeding a second cleaning step: completely removing the via photoresist layer by using reducing plasma.

2. The two-step stripping method according to claim 1 wherein the hard mask layer further comprises a silicon carbide (SiC) layer and a silicon oxide layer, and the metal layer is interposed between the silicon carbide layer and the silicon oxide layer.

3. The two-step stripping method according to claim 1 wherein the metal layer is made of TiN or TaN.

4. The two-step stripping method according to claim 1 wherein the trench photoresist layer is 193 nm resist.

5. The two-step stripping method according to claim 1 wherein the via photoresist layer is 193 nm resist.

6. The two-step stripping method according to claim 1 wherein the hydrogen-free fluorocarbon plasma contains inert gas comprising helium, argon, or nitrogen.

7. The two-step stripping method according to claim 1 wherein hydrogen-free fluorocarbon plasma is carbon tetra-fluoride (CF₄) plasma.

8. The two-step stripping method according to claim 1 wherein the reducing plasma comprises N₂/H₂, He/H₂, and NH₃ plasma.

9. The two-step stripping method according to claim 1 wherein the dielectric layer is made of carbon-containing ultra low-k (ULK, k<2.5) materials.

10. A partial-via dual damascene process, comprising:
preparing a semiconductor substrate provided thereon with a dielectric layer, a hard mask layer over the dielectric layer, and a first bottom anti-reflection coating (BARC) layer over the hard mask layer, wherein the hard mask layer comprises a metal layer;
forming, on the first BARC layer, a pattern of a first photoresist layer comprising a trench opening exposing a portion of the subjacent first BARC layer;
etching the exposed first BARC layer and the underlying hard mask layer through the trench opening to form a trench recess in the hard mask layer;
stripping the first photoresist layer and the first BARC layer;
depositing a second BARC layer over the hard mask layer and filling the trench recess thereof;
forming, on the second BARC layer, a pattern of a second photoresist layer comprising a via opening, which is located above the trench recess, thereby exposing a portion of the subjacent second BARC layer;
etching the exposed second BARC layer, the underlying hard mask layer and the dielectric layer through the via opening to form a via recess in an upper portion of the dielectric layer;
contacting the second photoresist layer with CF₄ plasma for a time period not exceeding 20 seconds for removing metallic residues on surface of the second photoresist layer and preventing the dielectric layer from carbon depletion;
stripping the second photoresist layer by using reducing plasma; and
performing a dry etching to etch the dielectric through the via recess.

11. The partial-via dual damascene process according to claim 10 wherein the hard mask layer further comprises a silicon carbide (SiC) layer and a silicon oxide layer, and the metal layer is interposed between the silicon carbide layer and the silicon oxide layer.

12. The partial-via dual damascene process according to claim 10 wherein the metal layer is made of TiN or TaN.

13. The partial-via dual damascene process according to claim 10 wherein the first photoresist layer is 193 nm resist.

14. The partial-via dual damascene process according to claim 10 wherein the second photoresist layer is 193 nm resist.

15. The partial-via dual damascene process according to claim 10 wherein the dielectric layer is made of carbon-containing ultra low-k (ULK, k<2.5) materials.

16. The partial-via dual damascene process according to claim 10 wherein the CF₄ plasma contains inert gas comprising helium, argon, or nitrogen.

17. The partial-via dual damascene process according to claim 10 wherein the reducing plasma comprises N₂/H₂, He/H₂, and NH₃ plasma.
